(19) United States
(12) Patent Application Publication
(10) Pub. No.: US 2008/0030973 A1
(43) Pub. Date: Feb. 7, 2008

(54) Method for the production of a sensor and sensor

(75) Inventor: Greorg Mascha, Radolfzell (DE)

Correspondence Address: TAROLLI, SUNDHEIM, COVELL & TUMMINO L.L.P., 1300 EAST NINTH STREET, SUITE 1700, CLEVEVLAND, OH, 44114, US

(73) Assignee: TRW Automotive GmbH

(21) Appl. No.: 11/888,405

(22) Filed: Aug. 1, 2007

(30) Foreign Application Priority Data
Aug. 7, 2006 (DE) 10 2006 036 792.8

(51) Int. Cl. H05K 7/02; G01D 5/12; G01M 17/007; G01P 15/00; H05K 3/30

(52) U.S. Cl. 361/807; 29/841

(57) ABSTRACT

A method for the production of a sensor, especially of a crash sensor for a vehicle safety system, with the following steps: provision of a housing base part (12), placement of a circuit board (16) holding at least one sensor component (18) into the housing base part (12) and production of a housing cover part (14), involving at least partial encapsulation by injection molding of the circuit board (16), in which process step the housing cover part (14) is injection-molded directly onto the housing base part (12) and the circuit board (16) is joined directly to the housing cover part (14) and is hermetically enclosed by the housing base (12) and the housing cover part (14).

### FIELD OF THE INVENTION

The invention relates to a method for the production of a sensor, especially of a crash sensor for a vehicle safety system, as well as a sensor.

### BACKGROUND OF THE INVENTION

A sensor of this type normally has one or more electronic components that are responsible for the actual detection of a change in the state of a variable. The electronic parts are mounted on a carrier material, for example, a lead frame or a circuit board, and surrounded by a housing. The housing has a connector section via which the electronic components situated inside the housing are electrically contacted.

Such sensors which, for example, pick up an acceleration of a vehicle, have to function reliably over the entire lifetime of the vehicle. At the same time, of course, they should take up as little space as possible and should also be inexpensive to produce.

### BRIEF SUMMARY OF THE INVENTION

It is an object of the invention to provide a sensor that fulfills the above-mentioned criteria.

This is achieved in a method for the production of a sensor that comprises the following steps: provision of a housing base part, placement of a circuit board holding at least one sensor component into the housing base part and fabrication of a housing cover part, involving at least partial encapsulation by injection molding of the circuit board, in which process step the housing cover part is injection-molded directly onto the housing base part and the circuit board is joined directly to the housing cover part and is hermetically enclosed by the housing base and the housing cover part. Since the housing cover part is injection-molded directly onto the housing base part, a stable gas-tight and liquid-tight connection is formed between the housing parts. The housing base part may be prefabricated so that only one single injection molding process is required.

The circuit board is preferably placed into the housing base part in such a way that the sensor component protrudes into a receptacle of the housing base part. The receptacle is preferably configured in such a way that the sensor component lies in a hollow space formed by the housing base part and by the circuit board. In this manner, the sensor component is protected on all sides by the housing parts. The sensor component is shielded by the housing base part and the circuit board, also during the injection molding procedure, from the plastic material employed as well as from the high temperatures.

In the housing base part, a circuit board attachment can be formed that predefines the position of the circuit board relative to the housing base part. This speeds up the assembly procedure since the circuit board will already be exactly positioned by putting it into place.

Preferably, the housing base part has a connector region.

The circuit board can have an edge connector and can be placed into the housing base part in such a way that the edge connector protrudes into the connector region. The circuit board can also have two contact pins that are separate from the circuit board but securely joined to the circuit board, which can be placed into the housing base part in such a way that the contact pins protrude into the connector region. In one case, the contact is formed by a section of the circuit board itself, while in the second case, it is formed by contact pins that are separate but securely joined to the circuit board. As an alternative, it is also possible to already configure the contacts with the housing base part and to join contact ends facing the circuit board to said circuit board after it has been put in place.

In a preferred embodiment of the invention, the connector region is connected via a passage to the receptacle for the circuit board before the housing cover is fabricated.

When the housing cover is produced, the passage is advantageously completely closed, as a result of which a hermetic seal is created in a simple manner between the receptacle of the circuit board and the connector region that is open towards the outside.

The shape of the sensor housing is preferably largely defined by the housing base part. The housing base part can be substantially larger than the housing cover part. Basically, the housing cover part only has to consist of a closure plate for the receptacle that covers the circuit board and only has to have slightly larger dimensions than the circuit board. Since the only housing part made by injection molding with the circuit board put into place is the housing cover part, the temperature load on the sensor elements remains slight.

Preferably, the housing cover part is produced using the same material of which the housing base part is made, so that a uniform and secure connection can be formed.

Another object of the invention is to provide a sensor functioning reliably over the entire lifetime of the vehicle and being inexpensive to produce.

This is achieved by a sensor with a housing comprising a housing base part and a housing cover part, as well as a circuit board holding at least one sensor component. The housing base part and the circuit board surround a hollow space into which the sensor component protrudes, whereas the circuit board and the housing cover part are inseparably joined to each other. The inseparable connection is preferably created by injection molding the housing cover part to the housing base part with the circuit board put into place, said housing cover part extending essentially parallel to the circuit board and preferably being connected to the back of the circuit board over a large area.

### SHORT DESCRIPTION OF THE DRAWINGS

FIG. 1 shows a schematic sectional view of a sensor according to the invention in a first embodiment, mounted onto a car body;

FIG. 2 shows a general schematic sectional view of the sensor in FIG. 1;

FIG. 3 shows a schematic exploded view of the sensor in FIG. 1;

FIG. 4 shows a perspective view of the sensor in FIG. 3 before the injection molding of the housing cover part;

FIGS. 5 to 8 show various views of the sensor according to the first embodiment;

FIG. 9 shows a schematic view of a first variant of a circuit board of the sensor according to the invention, seen from its bottom;

FIG. 10 shows the circuit board from FIG. 9, seen from its top;

FIG. 11 shows a second variant of a circuit board of a sensor according to the invention, seen from its bottom;

FIG. 12 shows the circuit board in FIG. 11, seen from its top;

FIG. 13 shows a schematic exploded view of a sensor according to a second embodiment of the invention;

FIG. 14 shows the sensor in FIG. 13 after the circuit board has been put into place and before the housing cover part is injection molded;

FIG. 15 shows a schematic view of the connector region of the sensor in FIG. 13;

FIG. 16 shows a schematic exploded view of a sensor according to a the third embodiment of the invention;

FIGS. 17 to 19 show perspective views of the housing base part in FIG. 16 with the contact pins already put into place; and

FIGS. 20 to 23 show several perspective views of the sensor according to the third embodiment of the invention.

### DETAILED DESCRIPTION OF PREFERRED EMBODIMENTS

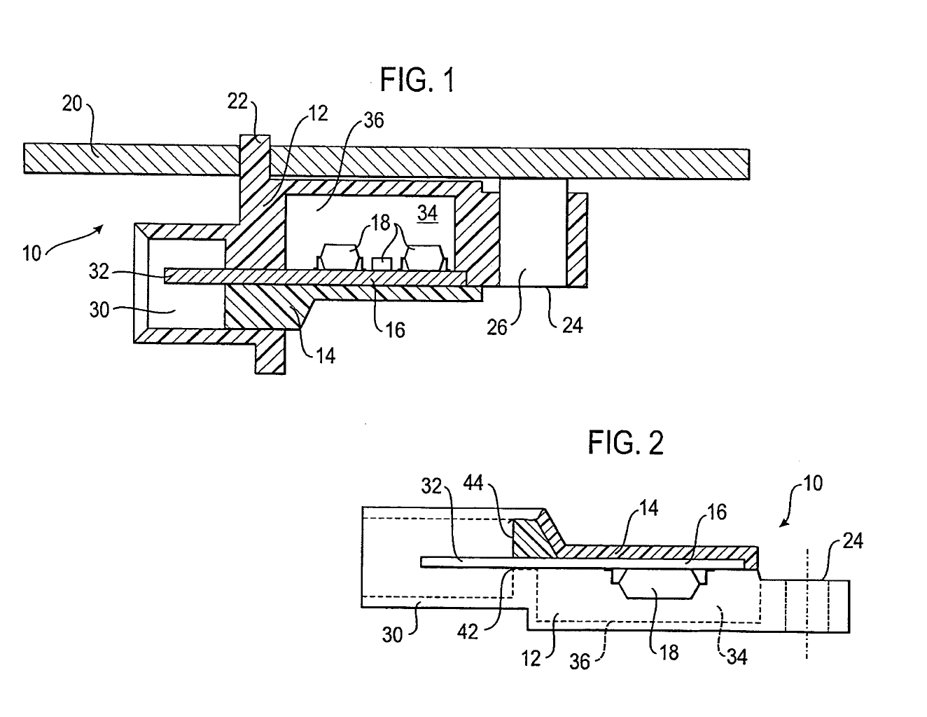

FIGS. 1 through 8 show a sensor 10 for use in a vehicle safety system. In this context, it should be pointed out that all of the described sensors can, of course, be used in any desired suitable area of application, without being restricted to vehicles or safety technology.

The sensor 10 has a housing that consists of a housing base part 12 and a housing cover part 14. A circuit board 16 is situated between the housing base part 12 and the housing cover part 14, and this circuit board 16 carries at least one electronic sensor element 18. The electronic sensor element 18 can be, for example, an acceleration sensor, a temperature sensor or any other desired electronic component.

The housing base part 12 has one or more injection-molded fastening pins 22 for attaching it to another component, here a car body 20, and these fastening pins 22 protrude through corresponding openings in the car body 20 in order to position the sensor 10.

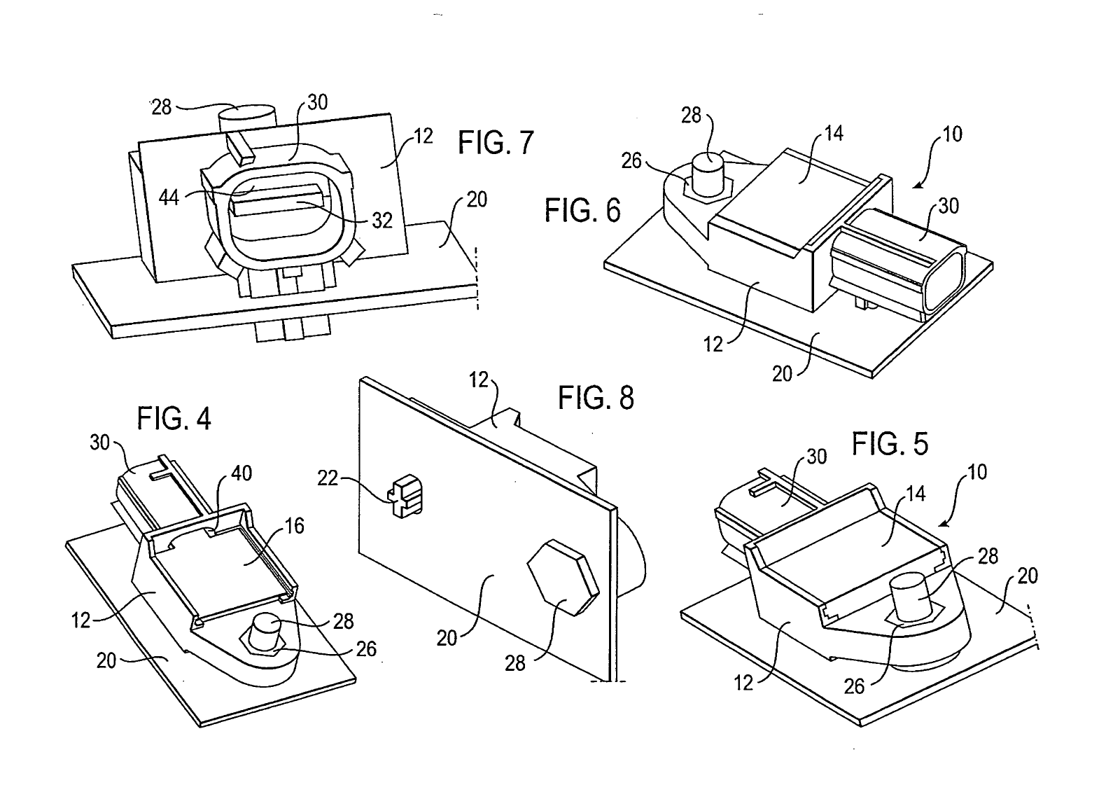

Further, the housing base part 12 for fastening the sensor 10 to the car body 20 has a through opening 24 through which a fastening means 28 (see, for example, FIGS. 4 to 8) can be inserted, said fastening means 28 being, for instance, a screw. The opening 24 can be reinforced, for example, by a sleeve 26 made of metal that is configured, for instance, with an internal thread and outwardly shaped hexagonally, so that the fastening means 28 can be screwed directly onto the sensor 10. The sleeve 26 can also be joined already during the production to the housing base part 12 by injection molding it together with the housing base part 12.

Another way (not shown here) to fasten the sensor 10 is to already injection-mold a fastening means into the housing base part 12, for instance, a bolt or a screw that protrudes partially out of the housing base part 12 and that can be inserted through an opening on the car body 20, for example, so as to be affixed with a nut.

The sensor 10, or to put it more precisely, the housing base part 12, has a connector region 30 for electrically contacting the sensor 10, for example, to an on-board electronic system (not shown here).

Here, the connector region 30 is a bushing (shown in greater detail, for example, in FIGS. 4 to 7) that is integrally formed with the housing base part 12 and that surrounds an electric contact region 32 of the circuit board 16 and projects beyond it in the lengthwise direction of the sensor 10. The electric contact region 32 is described in greater detail below.

The housing base part 12 has a receptacle 36. The circuit board 16 is placed “upside down” onto the housing base part 12 so that it lies on the housing base part 12 in the area of the edge 38 of the receptacle 36. The geometry of the area of the edge 38 of the receptacle 36 is selected in such a way that a precise positioning and attachment of the circuit board 16 are automatically achieved when the circuit board 16 is put onto the receptacle 36. The edge 38 of the receptacle 36 is graduated and shaped in such a way that it forms a circuit board attachment for the circuit board 16. Merely placing the circuit board 16 into the receptacle 36 already ensures that the circuit board 16 is situated at exactly the right place. This kind of circuit board attachment also ensures the exact positioning of the electric contact region 32 of the circuit board 16 in the connector region 30.

The sensor components 18 protrude into the receptacle 36. Here, they can be at a distance from the walls of the receptacle 36. The sensor components 18 are now lying in a hollow space 34 that is surrounded by the housing base part 12 and the circuit board 16. The hollow space 34 can remain unchanged and empty during the production of the sensor or else it can be filled with a suitable material.

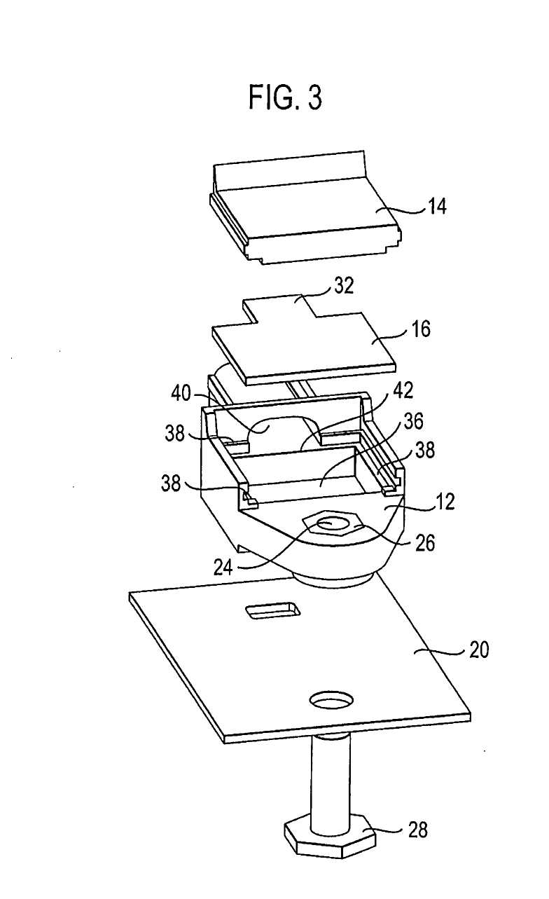

The housing base part 12 has a passage 40 that creates a connection between the receptacle 36 and the connector region 30 (see, for example, FIGS. 3, 4 and 14).

In order to produce the sensor 10, first of all, the housing base part 12 is made, for example, by means of an injection-molding process. Then the circuit board 16 fitted with the sensor components 18 is placed into the housing base part 12 in such a way that it lies against the housing base part 12 in the area of the receptacle 36 and the electric contact region 32 of the circuit board 16 protrudes through the passage 40 into the connector region 30. The circuit board 16, together with the receptacle 36, delimits the hollow space 34, and the sensor components 18 protrude into the receptacle 36 of the housing base part 12. This state is shown for the various embodiments in FIGS. 4, 14 and 18.

In the next processing step, the assembly unit consisting of the housing base part 12 and the circuit board 16 is placed into an injection mold (not shown) and the housing cover part 14 is integrally connected thereto in the following injection molding process. The housing cover part 14 is made entirely by means of this injection molding step. In this process, the housing cover part 14 is thus joined to the back of the circuit board 16 and to the edges 38 of the receptacle 36 in such a way that the hollow space 34 is hermetically sealed. The sensor components 18 are arranged on the side of the circuit board 16 facing away from the housing cover part 14 made in the injection molding step.

The lower edge 42 of the passage 40 lies flush with the inserted circuit board 16 (see FIG. 2). When the housing cover part 14 is injection-molded onto the housing base part 12, the passage 40 is completely and hermetically sealed, while the contact region 32 continues to protrude into the connector region 30. This state can be clearly seen in FIGS. 7 and 15 in which the part of the passage 40 situated above and next to the contact region 32 is closed by a section 44 of the housing cover part 14. In this process step, the position of the contact region 32 is also completely affixed in place in all spatial directions by the section 44.

In this example, the material used for the housing cover part 14 is the same material as that used for the housing base part 12. Here, any suitable plastic that can be injection molded can be used. Preferably, however, a plastic with the lowest possible injection molding temperature is used so as to not unduly stress the sensor components 18.

No other components, for example, separate gaskets, are needed in order to hermetically seal the circuit board 16 and the sensor components 18 from the surroundings of the sensor 10.

The arrangement of the sensor components 18 with respect to the housing base part 12 is the opposite of the approach that is usually taken. Normally, the circuit board is placed onto a support part in such a way that the sensor components face away from this support part. Then, further steps are carried out, namely, the placement of a housing cover, the filling with melt adhesives or the like. According to the invention, however, the circuit board 16 is put into place in a reversed position, namely, with the sensor components 18 facing the housing base part 12. Thus, the circuit board 16 itself forms a first “cover” that closes the hollow space 34 with the sensor components 18. During the subsequent injection molding process, the circuit board 16 is encapsulated over a large area by the housing cover part 14, thus being inseparably joined to the housing cover part 14. At the edges 38 of the housing base part 12 located next to the circuit board 16, the housing cover part 14 is joined to the housing base part 12, giving rise to an essentially one-piece housing.

The individual embodiments differ mainly in terms of the shape of the electric contact region 32.

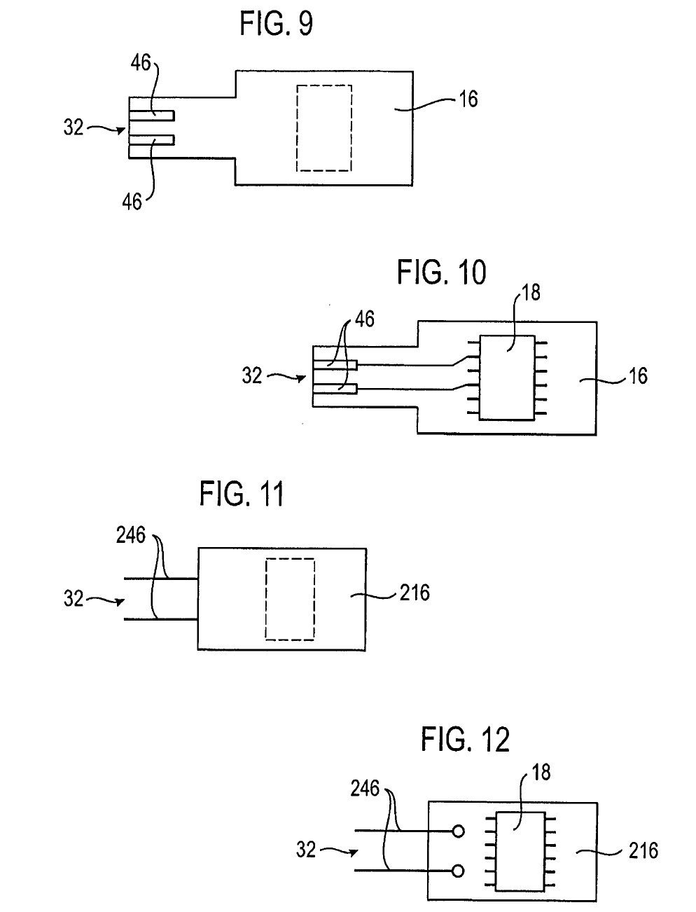

In the above-described first embodiment according to FIGS. 1 to 10, the electric contacts 46 are formed on the circuit board 16 itself, for example, in the form of an edge connector. In this case, the electric contact region 32 can be shaped so as to be narrower than the rest of the circuit board 16 and can thus be adapted to the shape of a connector that is to be plugged thereon.

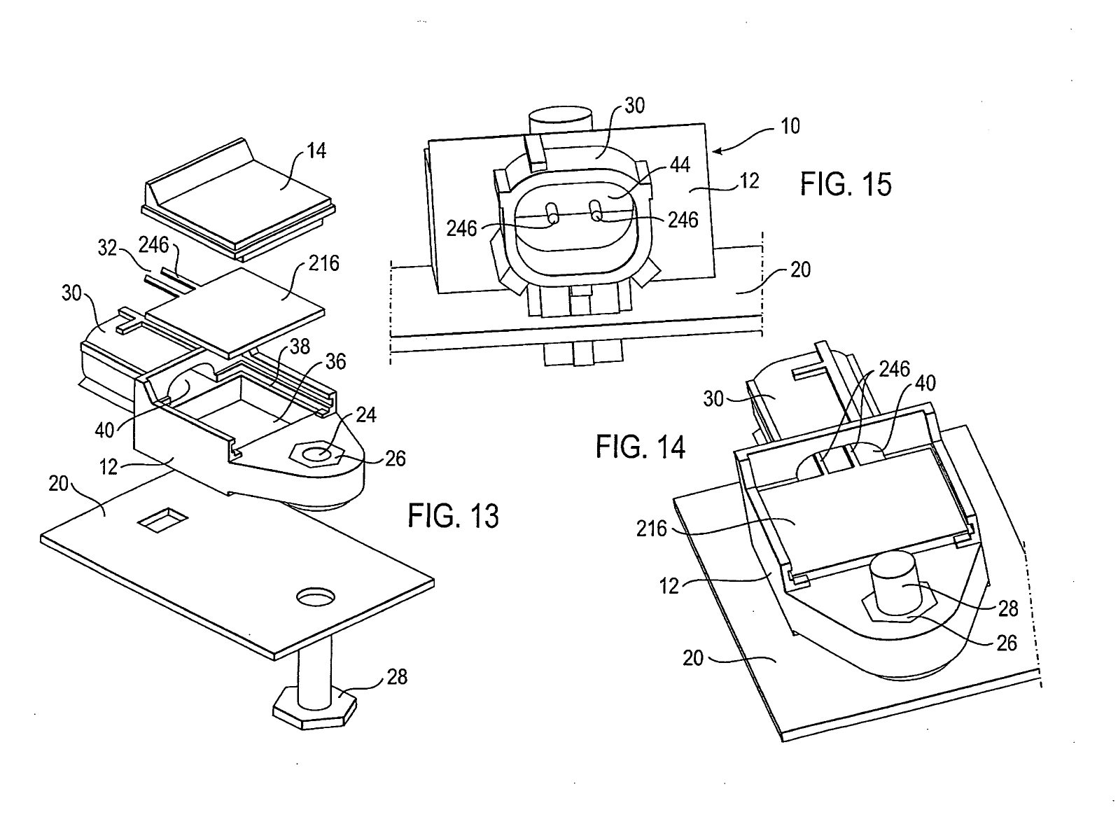

The second embodiment described with respect to FIGS. 11 to 15 differs from the first embodiment in that the electric contact region 32 is formed by two contact pins 246 that are separate from each other and that, in turn, are securely joined, for example, by soldering or force-fitting, to the electric contact regions of the circuit board 216 already before the circuit board 16 is inserted into the housing base part 12 (see FIG. 12). Only these contact pins 246 protrude through the passage 40 so that only the ends of the contact pins 246 are arranged in the connector region 30 (see FIG. 15), while the circuit board 216 itself is completely enclosed by the housing base part 12 and by the housing cover part 14, and is separated from the surroundings of the sensor 10. Both of the contact pins 246 are surrounded by the section 44 of the housing cover part 14 and partially embedded therein.

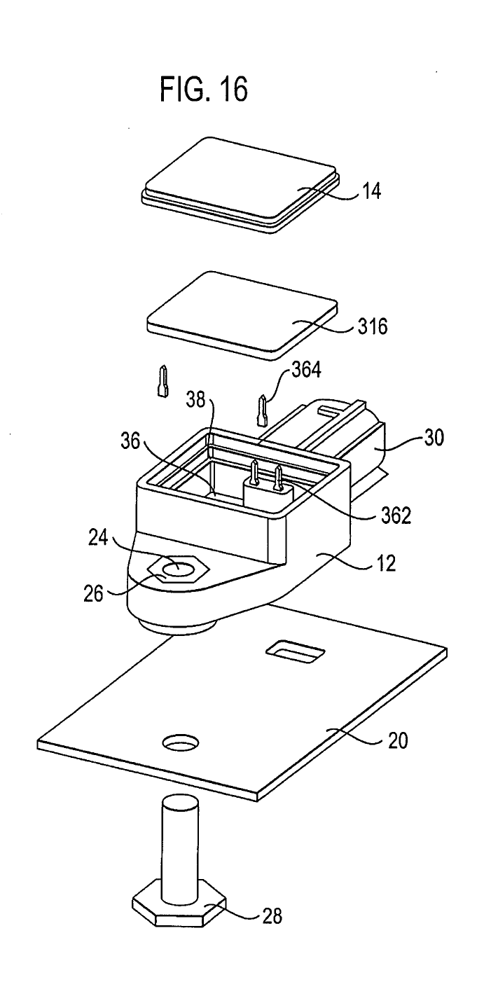

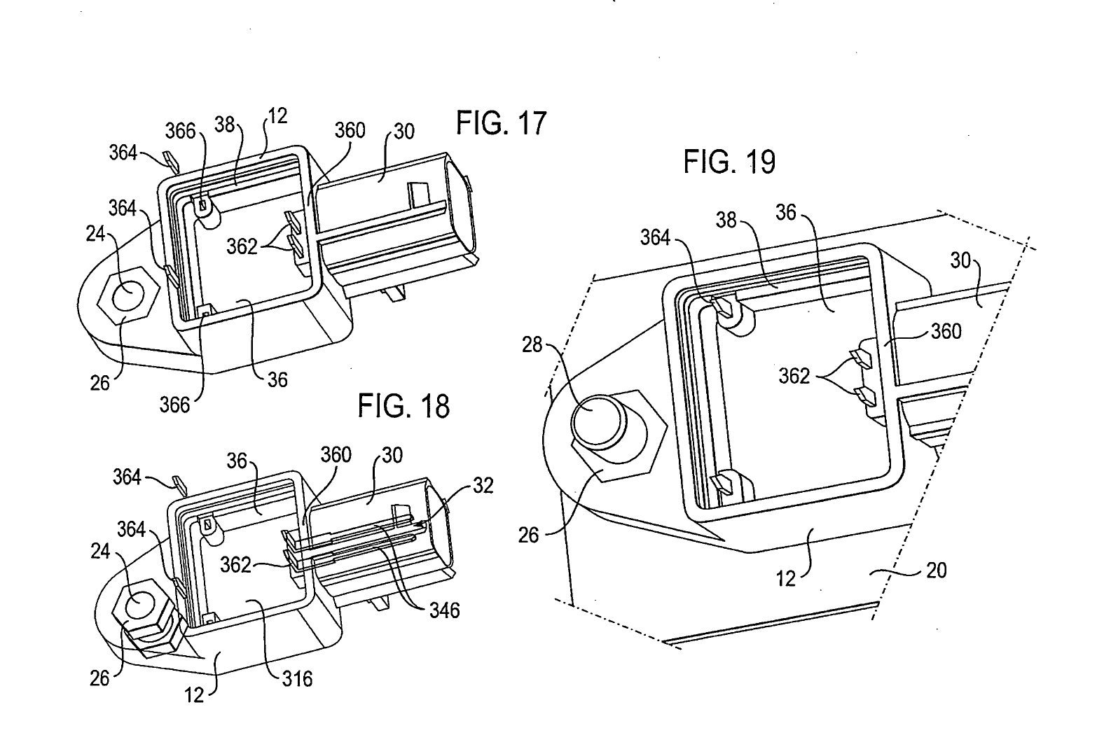

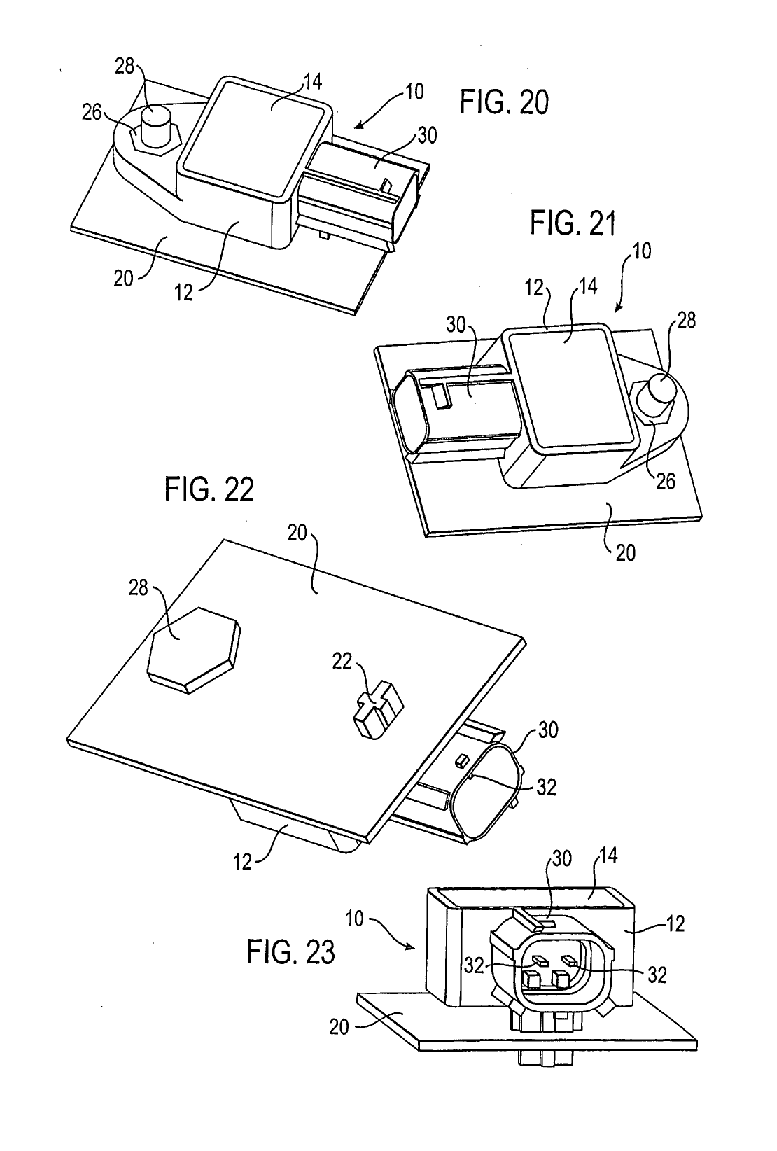

In contrast, in the third embodiment shown in FIGS. 16 to 23, the electric contact region 32 arranged in the connector region 30 forms part of the housing base part 12. For this purpose, two contact pins 346 are provided in the housing base part 12 which, for example, are integrated into the housing base part 12 during the injection-molded thereof. Hence, no passage exists that is closed by the housing cover part 14, but rather, the housing base part 12 has a media-tight wall 360 at the transition between the connector region 30 and the receptacle 36, and the ends of the contact pins 346 protrude through said wall 360 into the receptacle 36 or into the connector region 30.

In the receptacle 36, the ends 362 of the contact pins 346 are angled in the direction of the circuit board 316. The circuit board 316 has electric contact points (not shown here) that establish the electric contact to the ends 362 of the contact pins 346.

Further, in the example shown, two additional pins 364, one each at the corners of the receptacle 36 that are opposite from the contact pins 346, are pressed into receptacles 366 in the housing base part 12 and they serve to affix and position the circuit board 316 in the receptacle 36.

In the third embodiment as well, after the circuit board 316 has been put into place, the injection molding step in which housing cover part 14 is produced and thus joined to the housing base part 12 is carried out in such a way that the receptacle 36 is hermetically sealed.

1. A method for the production of a sensor, especially of a crash sensor for a vehicle safety system, comprising the following steps:
a) provision of a housing base part (12),
b) placement of a circuit board (16; 216; 316) holding at least one sensor component (18) into the housing base part (12) and
c) production of a housing cover part (14), involving at least partial encapsulation of the circuit board (16; 216; 316) by injection molding, the housing cover part (14) being injection-molded directly onto the housing base part (12) and the circuit board (16; 216; 316) being joined directly to the housing cover part (14) and being hermetically enclosed at least in sections by the housing base (12) and the housing cover part (14).

2. The method according to claim 1, wherein the circuit board (16; 216; 316) is placed into the housing base part (12) in such a way that the sensor component (18) protrudes into a receptacle (36) of the housing base part (12).

3. The method according to claim 2, wherein the sensor component lies in a hollow space (34) formed by the housing base part (12) and by the circuit board (16; 216; 316).

4. The method according to claim 1, wherein in the housing base part (12), a circuit board attachment is formed that predefines the position of the circuit board (16; 216; 316) relative to the housing base part (12).

5. The method according to claim 1, wherein the housing base part (12) has a connector region (30).

6. The method according to claim 5, wherein the circuit board (16) has an edge connector and is placed into the base housing part (12) in such a way that the edge connector protrudes into the connector region (30).

7. The method according to claim 5, wherein the circuit board (216) has two contact pins (246) that are separate from the circuit board (216) but securely joined to the circuit board (216), which can be placed into the base housing part (12) in such a way that the contact pins (246) protrude into the connector region (30).

8. The method according to claim 5, wherein, the circuit board (16; 216; 316) is placed into the housing base part (12) in such a way that the sensor component (18) protrudes into a receptacle (36) of the housing base part (12) and, before step c), the connector region (30) is joined to the receptacle (36) for the circuit board (16; 216) by a passage (40).

9. The method according to claim 8, wherein when the housing cover part (14) is produced, the passage (40) is completely closed.

10. The method according to claim 1, wherein the housing cover part (14) is produced using the same material of which the housing base part (12) is made.

11. A sensor comprising a housing having a housing base part (12) and a housing cover part (14) and a circuit board (16; 216; 316) holding at least one sensor component (18), the housing base part (12) and the circuit board (16; 216; 316) surrounding a hollow space (34) into which the sensor component (18) protrudes, and the circuit board (16; 216; 316) and the housing cover part (14) being inseparably joined to each other.
